(19) United States
(12) Patent Application Publication
(10) Pub. No.: US 2026/0282945 A1
(43) Pub. Date: Sep. 17, 2026

(54) SEMICONDUCTOR DEVICE AND MANUFACTURING METHOD THEREFOR

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Hiroaki KISHI, Himeji Hyogo (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/299,754

(22) Filed: Aug. 14, 2025

(30) Foreign Application Priority Data
Mar. 17, 2025 (JP) 2025-042803

(51) Int. Cl. H01L 23/00; H01L 21/56; H01L 23/31; H01L 23/495

(52) U.S. Cl. CPC H10W 70/417; H10W 72/073; H10W 72/07352; H10W 72/321; H10W 72/332; H10W 72/334; H10W 74/01; H10W 74/114; H10W 90/736

(57) ABSTRACT

A semiconductor device includes: a die pad; an adhesive member provided on the die pad and having conductivity; a semiconductor chip provided on the adhesive member; and an encapsulation member provided on the adhesive member and the semiconductor chip. The adhesive member has a central portion in contact with the semiconductor chip and a peripheral portion around the central portion. An upper surface of the peripheral portion has unevenness.

### CROSS-REFERENCE TO RELATED APPLICATIONS

This application is based upon and claims the benefit of priority from prior Japanese Patent Application No. 2025-042803, filed Mar. 17, 2025, the entire contents of which are incorporated herein by reference.

### FIELD

An embodiment of the present invention relates generally to a semiconductor device and a method for manufacturing the same.

### BACKGROUND

A semiconductor element such as a MOSFET is commercialized as a semiconductor package. A power device using a silicon carbide (SiC) substrate or the like can realize a high withstand voltage and a low on-resistance, and therefore a large drain current can flow.

For example, a drain electrode is provided on a bottom surface of the semiconductor element, and a source electrode and a gate electrode are provided on an upper surface of the semiconductor element. The semiconductor element is bonded on a die pad using solder or the like, and encapsulated a resin.

In a semiconductor device including such a semiconductor package, since adhesion between the solder and the resin is low, the resin may be delaminated from the solder. In this case, the reliability of the semiconductor device degrades. In addition, cracks may be formed in the peripheral portion of the solder. In particular, in a case where a temperature cycle test is performed on a semiconductor device, a crack is formed at the peripheral portion of the solder, and embrittlement of the solder is accelerated. Therefore, a resistance between the drain and the source increases.

### BRIEF DESCRIPTION OF DRAWINGS

FIG. 1 is a plan view of a semiconductor device according to a first embodiment.

FIG. 2 is a cross-sectional view of the semiconductor device taken along line A-A′ illustrated in FIG. 1.

FIG. 3 is an enlarged cross-sectional view of a partial area of the semiconductor device.

FIG. 4 is a plan view illustrating a process of a method for manufacturing the semiconductor device.

FIG. 5 is a cross-sectional view illustrating a process of the method for manufacturing the semiconductor device.

FIG. 6 is a plan view illustrating a process of the method for manufacturing the semiconductor device.

FIG. 7 is a cross-sectional view illustrating a process of the method for manufacturing the semiconductor device.

FIG. 8 is a cross-sectional view illustrating a process of the method for manufacturing the semiconductor device.

FIG. 9 is a plan view illustrating a process of the method for manufacturing the semiconductor device.

FIG. 10 is a cross-sectional view illustrating a process of the method for manufacturing the semiconductor device.

FIG. 11 is a plan view illustrating a process of the method for manufacturing the semiconductor device.

FIG. 12 is a cross-sectional view illustrating a process of the method for manufacturing the semiconductor device.

FIG. 13 is a plan view of a spanker according to a modification.

FIG. 14 is a cross-sectional view of the spanker taken along line C-C′ in FIG. 13.

FIG. 15 is a cross-sectional view illustrating a process of a method for manufacturing a semiconductor device according to the modification.

FIG. 16 is a plan view of a spanker according to a second embodiment.

FIG. 17 is a cross-sectional view of the spanker taken along line C-C′ in FIG. 16.

### DETAILED DESCRIPTION

In general, according to one embodiment, there is provided a semiconductor device comprising:
a die pad;
an adhesive member provided on the die pad and having conductivity;
a semiconductor chip provided on the adhesive member; and
an encapsulation member provided on the adhesive member and the semiconductor chip, wherein
the adhesive member has a central portion in contact with the semiconductor chip and a peripheral portion around the central portion, and
an upper surface of the peripheral portion has unevenness.

Hereinafter, embodiments will be described with reference to the drawings. Some embodiments described below illustrate an apparatus and a method for embodying the technical idea of the present invention, and the technical idea of the present invention is not specified by the shape, structure, arrangement, and the like of the components. In the following description, elements having the same functions and configurations are denoted by the same reference numerals, and redundant description will be omitted.

### (1) First Embodiment

### (1-1) Configuration of Semiconductor Device 1

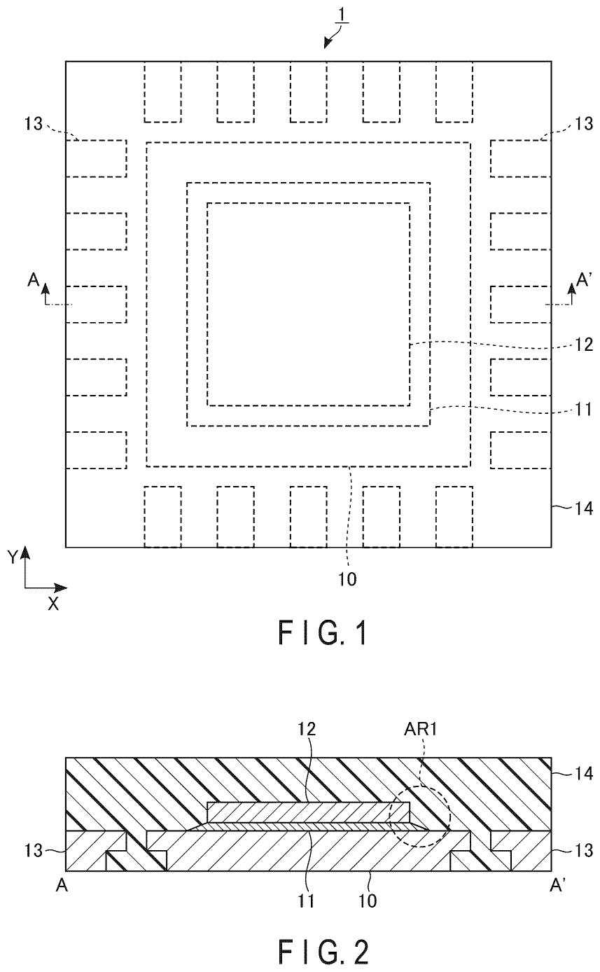

FIG. 1 is a plan view of a semiconductor device 1 according to a first embodiment. FIG. 2 is a cross-sectional view of the semiconductor device 1 taken along line A-A′ illustrated in FIG. 1. In FIG. 1, an X direction is a direction along a certain side of the semiconductor device 1, and a Y direction is a direction orthogonal to the X direction. The semiconductor device 1 includes a semiconductor chip and a semiconductor package that encapsulates the semiconductor chip. In the present embodiment, a quad flat non-leaded package (QFN) will be described as an example of the type of semiconductor package.

The semiconductor device 1 includes a die pad 10, a conductive adhesive member 11, a semiconductor chip 12, a plurality of terminals 13, and an encapsulation member 14.

The die pad 10 has a function of supporting and fixing the semiconductor chip 12. The die pad 10 has, for example, a rectangular shape. The die pad 10 is made of metal such as copper (Cu).

The adhesive member 11 is provided on the die pad 10. The adhesive member 11 has conductivity. The adhesive member 11 has a function of bonding the die pad 10 and the semiconductor chip 12. The adhesive member 11 is made of solder (including melt solder and solder paste) or silver (Ag) paste. In the present embodiment, a solder 11 will be described as an example of the adhesive member 11.

The semiconductor chip 12 is provided on the solder 11. The semiconductor chip 12 includes a semiconductor element. The semiconductor chip 12 includes, for example, an element mainly made of silicon (Si) or an element mainly made of silicon carbide (SiC). The semiconductor chip 12 includes, for example, a metal oxide semiconductor field effect transistor (MOSFET) or an insulated gate bipolar transistor (IGBT). In the present embodiment, a case where the semiconductor chip 12 is a MOSFET will be described as an example. The semiconductor chip 12 has, for example, a rectangular shape.

For example, a drain electrode is provided on a bottom surface of the semiconductor chip 12, and a source electrode and a gate electrode are provided on an upper surface thereof. The drain electrode of the semiconductor chip 12 is electrically connected to the die pad 10 via the solder 11. The semiconductor chip 12 is also called a die.

A plurality of terminals 13 is arranged around the die pad 10. The plurality of terminals 13 is provided, for example, on each of four sides of the semiconductor device 1. The plurality of terminals 13 is made of metal such as copper (Cu). The plurality of terminals 13 is electrically connected to the semiconductor chip 12 using a plurality of bonding wires (not illustrated).

The encapsulation member 14 encapsulates the semiconductor chip 12. The encapsulation member 14 has, for example, a rectangular shape. The encapsulation member 14 is made of resin.

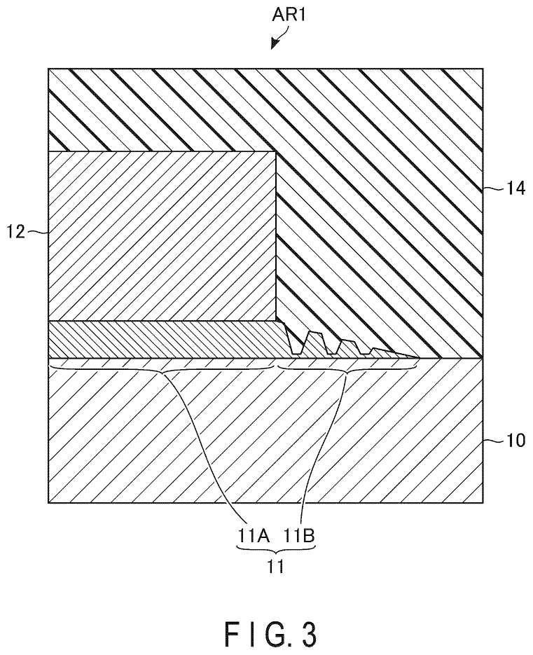

Next, a specific configuration of the solder 11 will be described. FIG. 3 is an enlarged cross-sectional view of a partial area (area AR1 in FIG. 2) of the semiconductor device 1. FIG. 3 schematically illustrates a shape of the solder 11. The actual shape of the solder 11 may have rounded corners.

An area of the solder 11 is set to be larger than an area of the semiconductor chip 12. That is, in plan view, the solder 11 is formed in such a way as to protrude from the semiconductor chip 12. The solder 11 has a central portion 11A and a peripheral portion 11B around the central portion 11A. The central portion 11A is a portion in contact with the semiconductor chip 12. The peripheral portion 11B is a portion protruding from the semiconductor chip 12.

An upper surface of the peripheral portion 11B has unevenness. The unevenness of the upper surface of the peripheral portion 11B is formed over the entire periphery of the peripheral portion 11B. Each of a plurality of grooves forming the unevenness of the solder 11 has a rectangular frame shape in plan view.

The encapsulation member 14 is provided on the peripheral portion 11B of the solder 11. The encapsulation member 14 is also formed in the groove of the peripheral portion 11B of the solder 11. The unevenness of the peripheral portion 11B exerts an anchor effect on the encapsulation member 14. That is, an adhesive force between the peripheral portion 11B of the solder 11 and the encapsulation member 14 is improved. This makes it possible to suppress delaminating of the encapsulation member 14 from the solder 11.

### (1-2) Manufacturing Method

Next, a method for manufacturing the semiconductor device 1 will be described with reference to the drawings. In the present embodiment, an area of the die pad 10 will be extracted and described, and illustration of the plurality of terminals 13 will be omitted. The plurality of terminals 13 is formed as a lead frame together with the die pad 10, and is formed in the same manufacturing process as that of the die pad 10.

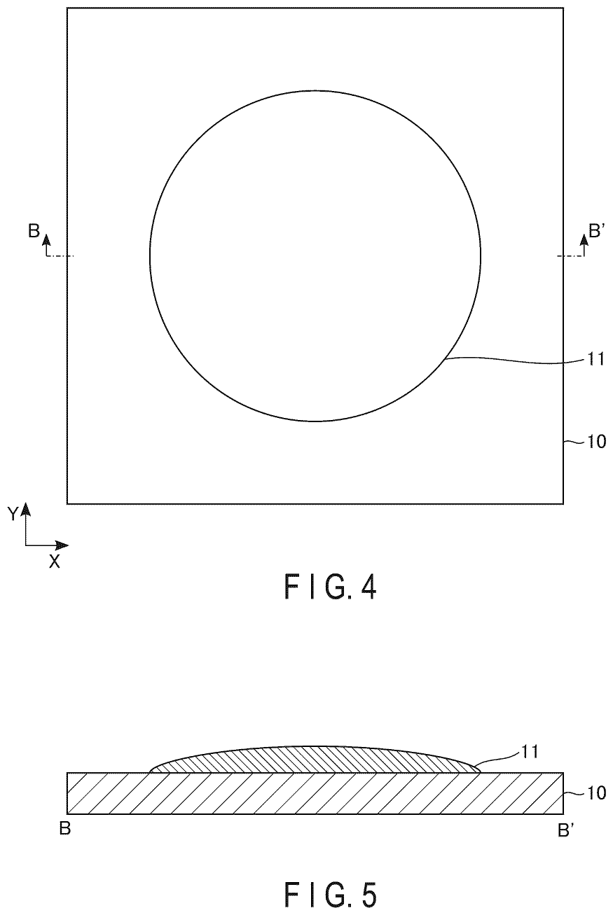

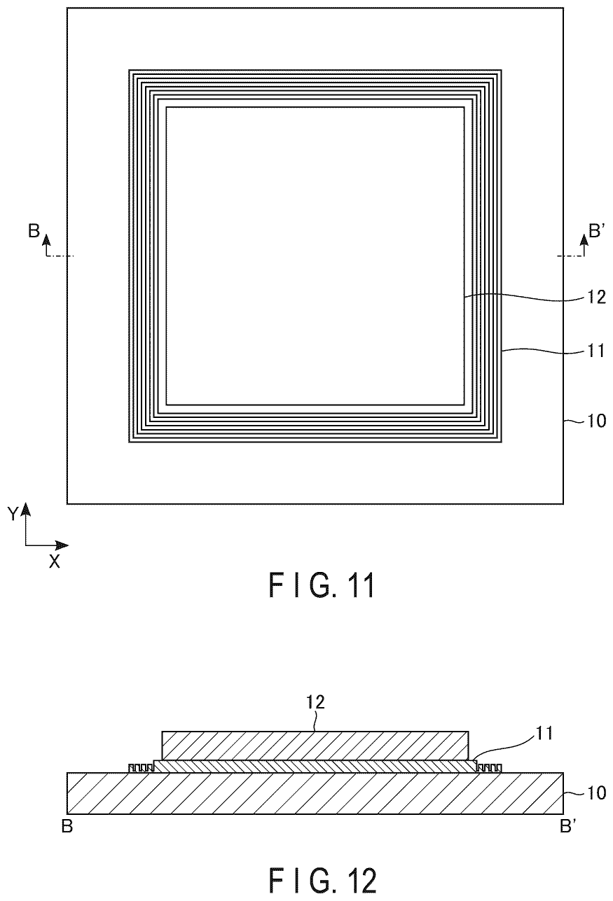

FIGS. 4 to 12 are views illustrating a process of the method for manufacturing the semiconductor device 1. FIGS. 4, 6, and 9 are plan views illustrating a process of the method for manufacturing the semiconductor device 1 in FIG. 11. FIGS. 5, 7, 8, 10, and 12 are cross-sectional views illustrating a process of the method for manufacturing the semiconductor device 1 taken along line B-B′ in the plan view.

As illustrated in FIGS. 4 and 5, the die pad 10 is prepared. Subsequently, the solder is melted using a solder supply device (not illustrated), and the solder 11 is applied on the die pad.

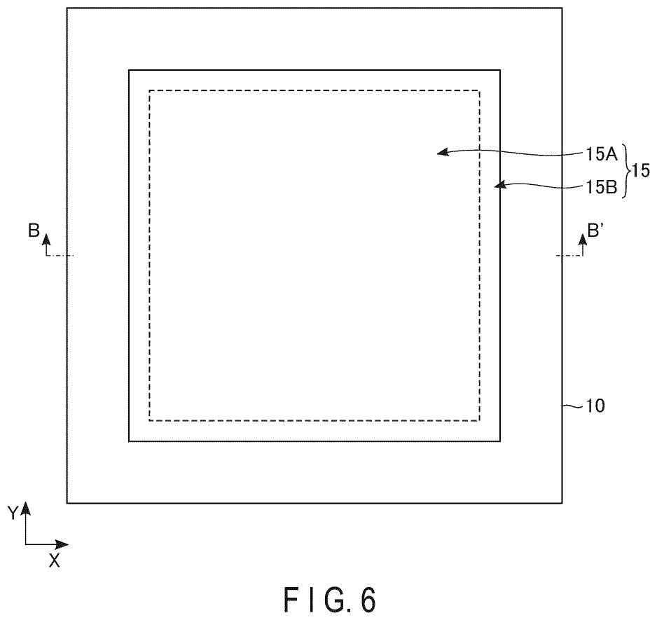

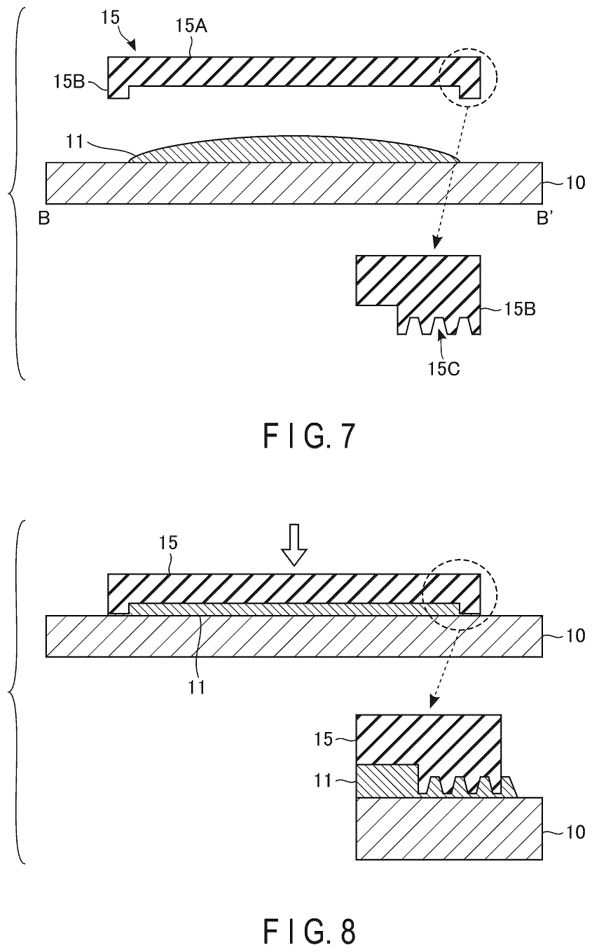

Subsequently, as illustrated in FIGS. 6 and 7, the spanker 15 is prepared. FIG. 7 also shows an enlarged view of a partial area (a portion surrounded by a dashed circle) of the spanker 15. The spanker is a device that molds the solder supplied by the solder supply device in a die bonding process in such a way as to have a uniform thickness and fit to a die size to be mounted. In the present embodiment, the spanker means a component that is in direct contact with the solder and forms the solder.

The spanker 15 is made of an insulating material, for example, hard rubber. The planar shape of the spanker 15 is rectangular or square. An area of the spanker 15 is set according to an area of the semiconductor chip 12, and is slightly larger than that of the semiconductor chip 12. The spanker 15 has a rectangular flat portion 15A and a protrusion 15B protruding downward from an outer peripheral portion of the flat portion 15A. The flat portion 15A has a flat bottom surface. The planar shape of the protrusion 15B is a rectangular frame shape. The protrusion 15B has a plurality of grooves 15C on the bottom surface thereof. Each of the plurality of grooves 15C is formed in parallel to each side of the outer periphery of the spanker 15. A planar shape of each of the plurality of grooves 15C is a rectangular frame shape. In FIG. 7, a configuration in which the protrusion 15B has three grooves 15C is illustrated as an example. The number and width of the grooves 15C can be arbitrarily set.

Subsequently, as illustrated in FIG. 8, the solder 11 is pressed from above by the spanker 15 to form the solder 11. The solder 11 is formed such that its upper surface is flat. Further, the peripheral portion of the solder 11 is molded so as to enter the grooves 15C of the spanker 15.

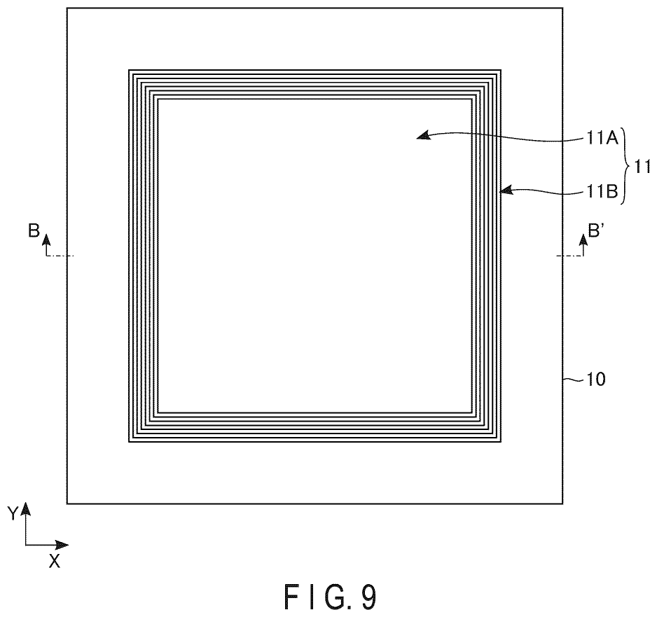

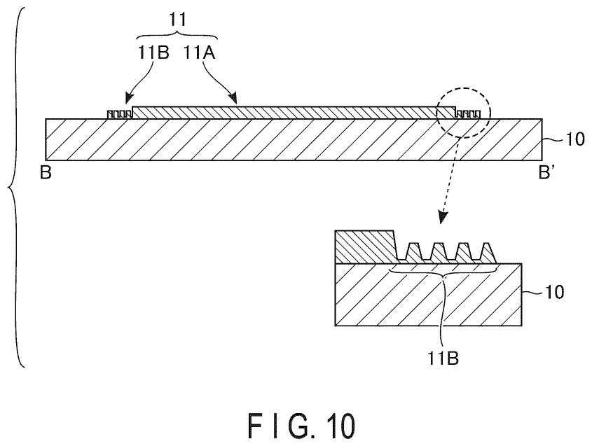

FIGS. 9 and 10 are views illustrating a manufacturing process after the solder 11 is molded. FIG. 10 also shows an enlarged view of a partial area (a portion surrounded by a dashed circle) of the solder 11. The solder 11 is configured to have a flattened central portion 11A and a peripheral portion 11B around the central portion 11A. The central portion 11A has a rectangular shape. The peripheral portion 11B has a rectangular frame shape. An upper surface of the peripheral portion 11B has unevenness. Each of the plurality of grooves forming the unevenness of the solder 11 has a rectangular frame shape. The unevenness formed on the upper surface of the peripheral portion 11B has, for example, a shape roughly corresponding to the shape of the grooves 15C of the spanker 15. The unevenness formed on the upper surface of the peripheral portion 11B may not completely match the shape of the grooves 15C. In this case, for example, the number of grooves 15C of the spanker 15 matches the number of projections of the unevenness formed on the upper surface of the peripheral portion 11B.

Subsequently, as illustrated in FIGS. 11 and 12, the semiconductor chip 12 is placed on the solder 11. Subsequently, although not illustrated, the semiconductor chip 12 and the plurality of terminals 13 are electrically connected using a plurality of bonding wires.

Subsequently, as illustrated in FIGS. 1 and 2, the encapsulation member 14 is formed so as to encapsulate the semiconductor chip 12 with a resin.

### (1-3) Modification

Next, a modification of the manufacturing method will be described.

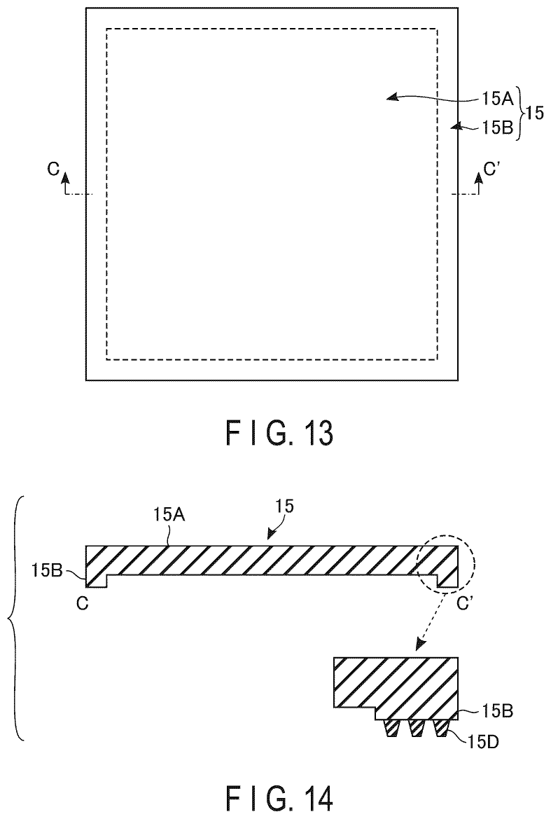

FIG. 13 is a plan view of a spanker 15 according to a modification. FIG. 14 is a cross-sectional view of the spanker 15 taken along line C-C′ of FIG. 13. FIG. 14 also shows an enlarged view of a partial area (a portion surrounded by a dashed circle) of the spanker 15.

The spanker 15 is made of an insulating material, for example, hard rubber. The spanker 15 has a rectangular flat portion 15A and a protrusion 15B protruding downward from an outer peripheral portion of the flat portion 15A. The bottom surface of the protrusion 15B is formed flat.

A plurality of protrusions 15D is provided on the bottom surface of the protrusion 15B. The plurality of protrusions 15D is made of an insulating material, for example, hard rubber. Each of the plurality of protrusions 15D is formed in parallel to each side of the outer periphery of the spanker 15. Each of the plurality of protrusions 15D has a rectangular frame shape. In FIG. 14, a configuration in which the spanker 15 has three protrusions 15D is illustrated as an example. The number and width of the protrusions 15D can be arbitrarily set.

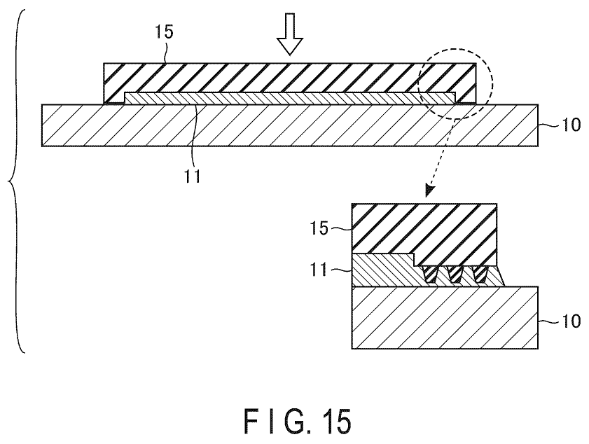

FIG. 15 is a cross-sectional view illustrating a process of the method for manufacturing the semiconductor device 1 according to the modification. As illustrated in FIG. 15, the solder 11 is pressed from above by the spanker 15 to form the solder 11. The peripheral portion of the solder 11 is molded so as to enter the gap between the plurality of protrusions 15D of the spanker 15. As described above, also in the modification, the unevenness can be formed in the peripheral portion of the solder 11. The unevenness formed on the upper surface of the peripheral portion 11B has, for example, a shape corresponding to the shape of the groove 15C of the spanker 15. The unevenness formed on the upper surface of the peripheral portion 11B may not completely match the shape of the grooves 15C. In this case, for example, the number of grooves 15C of the spanker 15 matches the number of projections of the unevenness formed on the upper surface of the peripheral portion 11B.

According to the first embodiment, unevenness is formed in the peripheral portion of the solder 11, and the encapsulation member 14 is formed such that the resin enters the unevenness. As a result, adhesion between the solder 11 and the encapsulation member 14 can be improved by the anchor effect of the solder 11, so that delaminating of the encapsulation member 14 from the solder 11 can be suppressed. In addition, adhesion between the solder 11 and the encapsulation member 14 can be improved. Therefore, it is possible to realize the semiconductor device 1 with high reliability.

In addition, since the adhesion between the solder 11 and the encapsulation member 14 is improved, generation of a crack in the solder 11 can be suppressed. As a result, the semiconductor device 1 with high reliability can be realized. In addition, it is possible to suppress an increase in resistance of the current path through the solder 11. For example, it is possible to suppress an increase in resistance (on-resistance) between the drain and the source of the MOSFET.

### (2) Second Embodiment

A second embodiment is another configuration example of the spanker 15, and the spanker 15 includes a material having a high thermal conductivity.

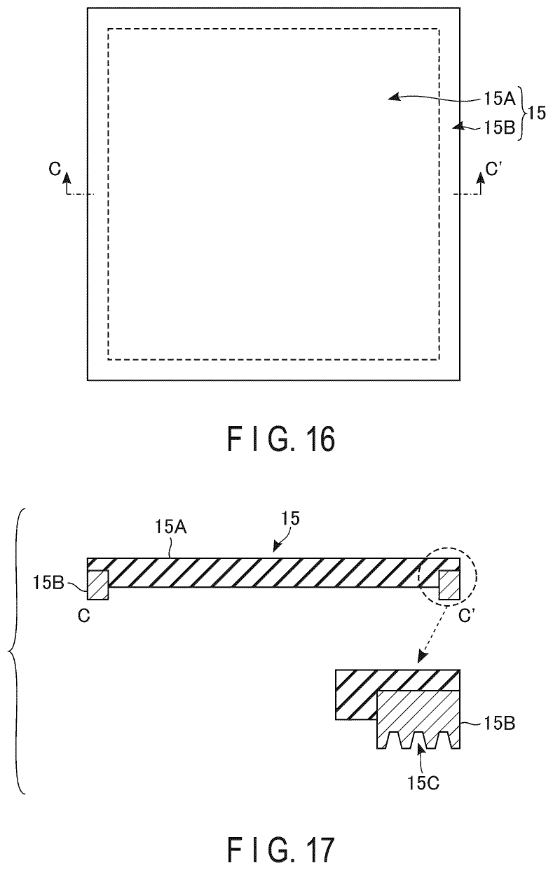

FIG. 16 is a plan view of the spanker 15 according to the second embodiment. FIG. 17 is a cross-sectional view of the spanker 15 taken along line C-C′ of FIG. 16. FIG. 17 also shows an enlarged view of a partial area (a portion surrounded by a dashed circle) of the spanker 15.

The spanker 15 has a rectangular flat portion 15A and a protrusion 15B protruding downward from an outer peripheral portion of the flat portion 15A. The bottom surface of the flat portion 15A is formed flat. The flat portion 15A is made of an insulating material, for example, hard rubber.

The protrusion 15B is made of a material having high thermal conductivity. The protrusion 15B is made of metal such as copper (Cu) or tungsten (W), for example. The protrusion 15B has a plurality of grooves 15C on the bottom surface thereof. Each of the plurality of grooves 15C is formed in parallel to each side of the outer periphery of the spanker 15. A planar shape of each of the plurality of grooves 15C is a rectangular frame shape. The number and width of the grooves 15C can be arbitrarily set.

A method for manufacturing the semiconductor device 1 is the same as that of the first embodiment. The solder 11 is molded using the spanker 15 according to the second embodiment. In this case, in the solder 11, a portion in contact with the flat portion 15A and a portion in contact with the protrusion 15B have different times during which the solder becomes a solid phase. That is, the solder portion in contact with the protrusion 15B becomes a solid phase faster than the solder portion in contact with the flat portion 15A. As a result, the unevenness of the peripheral portion 11B of the solder 11 is easily maintained. Thereafter, the encapsulation member 14 is formed so as to enter the unevenness of the solder 11.

According to the second embodiment, unevenness can be easily formed in the solder 11. As a result, adhesion between the solder 11 and the encapsulation member 14 can be improved.

In each of the above embodiments, the QFN has been described as an example of the semiconductor package, but the semiconductor package is not limited thereto. In the present embodiment, various semiconductor packages having die pads can be applied.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a die pad;
an adhesive member provided on the die pad and having conductivity;
a semiconductor chip provided on the adhesive member; and
an encapsulation member provided on the adhesive member and the semiconductor chip, wherein
the adhesive member has a central portion in contact with the semiconductor chip and a peripheral portion around the central portion, and
an upper surface of the peripheral portion has unevenness.

2. The semiconductor device according to claim 1, wherein the encapsulation member is configured to be in contact with the unevenness of the peripheral portion.

3. The semiconductor device according to claim 1, wherein each of a plurality of grooves configuring the unevenness of the adhesive member has a rectangular frame shape.

4. The semiconductor device according to claim 1, wherein the adhesive member includes solder.

5. The semiconductor device according to claim 1, wherein the encapsulation member is made of resin.

6. The semiconductor device according to claim 1, further comprising a plurality of terminals disposed around the die pad,
wherein the encapsulation member is configured to integrally encapsulate the die pad and the terminals.

7. A method for manufacturing a semiconductor device, the method comprising:
applying an adhesive member having conductivity on a die pad;
molding the adhesive member by using a spanker, the spanker including a flat portion, a protrusion protruding downward from an outer peripheral portion of the flat portion, and a plurality of grooves provided in the protrusion;
mounting a semiconductor chip on the adhesive member; and
forming an encapsulation member on the semiconductor chip and the adhesive member to encapsulate the semiconductor chip with a resin.

8. The method for manufacturing a semiconductor device according to claim 7, wherein
the protrusion has a rectangular frame shape, and
each of the grooves has a rectangular frame shape.

9. The method for manufacturing a semiconductor device according to claim 7, wherein the flat portion and the protrusion are made of an insulating material.

10. The method for manufacturing a semiconductor device according to claim 7, wherein
the flat portion is made of an insulating material, and
the protrusion is made of metal.

11. The method for manufacturing a semiconductor device according to claim 7, wherein the adhesive member includes solder.

12. The method for manufacturing a semiconductor device according to claim 7, wherein the encapsulation member is made of resin.

13. The method for manufacturing a semiconductor device according to claim 7, wherein
the adhesive member has a central portion in contact with the semiconductor chip and a peripheral portion around the central portion, and
an upper surface of the peripheral portion has unevenness formed by the grooves of the spanker.

14. The method for manufacturing a semiconductor device according to claim 13, wherein the encapsulation member is configured to be in contact with the unevenness of the peripheral portion.

15. The method for manufacturing a semiconductor device according to claim 13, wherein each of a plurality of grooves configuring the unevenness of the adhesive member has a rectangular frame shape.

16. The method for manufacturing a semiconductor device according to claim 13, wherein the number of projections of the unevenness of the adhesive member is equal to the number of the grooves of the spanker.
